(19) United States
(12) Patent Application Publication
(10) Pub. No.: US 2016/0018893 A1
(43) Pub. Date: Jan. 21, 2016

(54) HAPTIC FEEDBACK SCREEN USING PIEZOELECTRIC POLYMER

(71) Applicant: UNIVERSITY OF ULSAN FOUNDATION FOR INDUSTRY COOPERATION, Ulsan (KR)

(72) Inventors: Seung Tae CHOI, Ulsan (KR); Woo Eon JU, Ulsan (KR); Cheon Ho PARK, Pohang-si, Gyeongsangbuk-do (KR); Yong Ju MOON, Daegu (KR)

(21) Appl. No.: 14/772,785

(22) PCT Filed: Feb. 27, 2014
(86) PCT No.: PCT/KR2014/001634

§ 371 Date: Sep. 4, 2015

(30) Foreign Application Priority Data
Mar. 4, 2013 (KR) 10-2013-0023058

(51) Int. Cl. G06F 3/01; H01L 41/193; H01L 41/08; G06F 3/043

(52) U.S. Cl. CPC G06F 3/016; G06F 3/0433; H01L 41/193; H01L 41/08; G06F 2203/04103; G06F 2203/014

(57) ABSTRACT

The present invention relates to a haptic feedback screen using a piezoelectric polymer. The present invention provides a haptic feedback screen using a piezoelectric polymer, which comprises: a piezoelectric polymer layer made of a transparent piezoelectric polymer material; an upper electrode and a lower electrode disposed on an upper surface of and under a lower surface of the piezoelectric polymer layer, respectively, the upper electrode and the lower electrode being made of a transparent material; a transparent cover disposed on the upper electrode; and a transparent substrate disposed under the lower electrode, wherein the piezoelectric polymer layer generates vibration in a touch area by a power applied between the upper electrode and the lower electrode when a touch occurs on the transparent cover. The present invention can implement an overall or partial haptic feedback function by applying a transparent piezoelectric polymer material to a touch screen.

### BACKGROUND

a) Field

The present invention relates to a haptic feedback screen using piezoelectric polymer, and more particularly, to a haptic feedback screen using piezoelectric polymer capable of implementing a haptic feedback function on a touch screen.

b) Description of the Related Art

A touch screen refers to a device that can recognize a touched position through a touch sensor and then can perform a predetermined process by stored software if a finger of a person or an object touches a character displayed on a screen or a predetermined position.

Recently, a touch screen used in a portable electronic device has been developed in a direction to provide various physical user interfaces (UI) such as a visual, auditory, or tactile interface as feedback to the user's touch on the touch screen. Among the various physical user interfaces, a haptic feedback, which uses a tactile feedback method, is one that outputs a physical force to the user based on events occurring in various graphical environments or interaction between the events, and when a touch is sensed on the touch screen, the haptic feedback generates a vibration to be applied to the user such that the user feels a haptic sense.

Such a haptic feedback may not be easily implemented compared with a visual or auditory feedback. Until now, a gross vibration method that the portable electronic device entirely vibrates is generally used. However, it is difficult that such an gross vibration method is applied to a portable electronic device including a large size touch screen such as a smart pad because the gross vibration method is inefficient in the portable electronic device including the large size touch screen. Further, a haptic feedback method for a touch screen applicable to a flexible electronic device is not substantially developed.

Background technology of the present invention is disclosed at Korean Patent Laid-Open Publication No. 2011-0138629 Dec. 28, 2011).

The above information disclosed in this Background section is only to enhance the understanding of the background of the invention and therefore it may contain information that does not form the prior art that is already known in this country to a person of ordinary skill in the art.

### SUMMARY

The present invention has been made in an effort to provide a haptic feedback screen using a piezoelectric polymer that can implement an overall or partial haptic feedback function by applying a transparent piezoelectric polymer material to a touch screen.

An exemplary embodiment of the present invention provides a haptic feedback screen using a piezoelectric polymer, including: a piezoelectric polymer layer formed of a transparent piezoelectric polymer material; an upper electrode and a lower electrode respectively disposed on an upper surface and a lower surface of the piezoelectric polymer layer and formed of a transparent material; a transparent cover disposed over the upper electrode; and a transparent substrate disposed below the lower electrode, wherein the piezoelectric polymer layer may generate a vibration in a touch region by a power applied between the upper electrode and the lower electrode when a touch occurs on the transparent cover.

Another exemplary embodiment of the present invention provides a haptic feedback screen using a piezoelectric polymer, including: a piezoelectric polymer layer formed of a transparent piezoelectric polymer material; an upper electrode disposed over the piezoelectric polymer layer with a gap therebetween and formed of a flexible and transparent material; a transparent cover disposed over the upper electrode and formed of a flexible material; spacer disposed at edge between the piezoelectric polymer layer and the upper electrode to form the gap; a lower electrode disposed on a lower surface of the piezoelectric polymer layer and formed of a transparent material; and a transparent substrate disposed under the lower electrode.

Yet another embodiment of the present invention provides a haptic feedback screen using a piezoelectric polymer, including: a piezoelectric polymer layer formed of a flexible and transparent piezoelectric polymer material; a lower electrode disposed under the piezoelectric polymer layer with a gap therebetween and formed of a transparent material; a transparent substrate disposed under the lower electrode; spacer disposed at edge between the piezoelectric polymer layer and the lower electrode to form the gap; an upper electrode disposed on an upper surface of the piezoelectric polymer layer and formed of a flexible and transparent material; and a transparent cover disposed over the upper electrode and formed of a flexible material.

When a touch occurs on the transparent cover, the transparent cover and the upper electrode may be bent and deformed, a deformed portion of the upper electrode may contact a partial surface of the piezoelectric polymer layer, and at the same time, an electric field partially may increase in the partial surface of the piezoelectric polymer layer, such that an acoustic wave may be generated.

When a touch occurs on the transparent cover, the piezoelectric polymer layer together with the transparent cover and the upper electrode may be bent and deformed, a deformed portion of the piezoelectric polymer layer may contact a partial surface of the lower electrode, and at the same time, an electric field partially may increase in the deformed portion of the piezoelectric polymer layer, such that an acoustic wave may be generated.

The piezoelectric polymer layer, the lower electrode, the spacer, and the transparent substrate may be formed of a flexible material.

The piezoelectric polymer layer may generate a vibration in the touch region by a power applied between the upper electrode and the lower electrode when a touch occurs on the transparent cover.

The transparent substrate may be formed of a material of higher strength than that of the transparent cover.

The piezoelectric polymer layer may be formed of a ferroelectric polymer material of PVDF or P(VDF-TrFE) or formed a relaxor ferroelectric polymer material of P(VDF-TrFE-CFE), P(VDF-TrFE-CTFE), or electron-irradiated P(VDF-TrFE).

The haptic feedback screen using the piezoelectric polymer may further include a plurality of dot spacers formed of a transparent material, having a height lower than the gap, and arranged to assist the spacer in a constant interval on an upper or lower surface of the piezoelectric polymer layer, a lower surface of the upper electrode, or an upper surface of the lower electrode that corresponds to the inside of the edge.

According to embodiments of the present invention, it is possible to implement an overall or partial haptic feedback function by applying a transparent piezoelectric polymer material to a touch screen. In addition, according to embodiments of the present invention, it is possible to commercially use a localized haptic feedback technology by forming a transparent piezoelectric actuator using a transparent piezoelectric polymer material on a surface of a display element and to provide a transparent and flexible actuator that is able to implement the haptic feedback function on the touch screen.

### BRIEF DESCRIPTION OF THE DRAWINGS

FIG. 1 illustrates a cross sectional view of a haptic feedback screen using a piezoelectric polymer according to a first exemplary embodiment of the present invention.

FIG. 2 illustrates a cross sectional view of a haptic feedback screen using a piezoelectric polymer according to a second exemplary embodiment of the present invention.

FIG. 3 illustrates an example of driving the exemplary embodiment of FIG. 2.

FIGS. 4 and 5 illustrate exemplary diagrams in which dot spacers are included in the exemplary embodiment of FIG. 2.

FIG. 6 illustrates a cross sectional view of a haptic feedback screen using a piezoelectric polymer according to a third exemplary embodiment of the present invention.

FIGS. 7 and 8 illustrate an exemplary diagram in which a dot spacer is included in the exemplary embodiment of FIG. 6.

### DETAILED DESCRIPTION OF THE EMBODIMENTS

The present invention will be described more fully hereinafter with reference to the accompanying drawings, in which exemplary embodiments of the invention are shown.

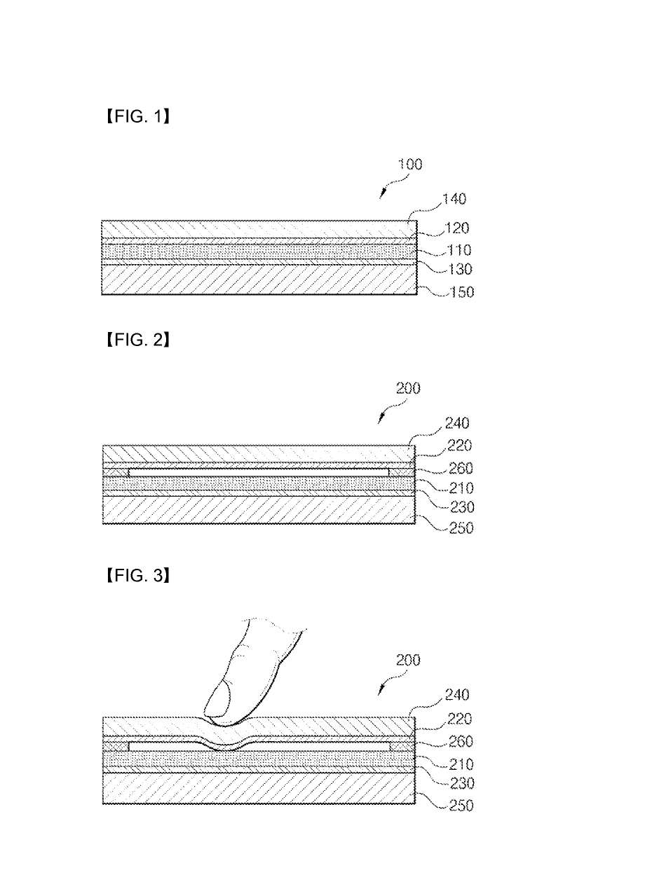

FIG. 1 illustrates a cross sectional view of a haptic feedback screen using a piezoelectric polymer according to a first exemplary embodiment of the present invention. Referring to FIG. 1, a haptic feedback screen 100 according to a first exemplary embodiment of the present invention includes a piezoelectric polymer layer 110, an upper electrode 120, a lower electrode 130, a transparent cover 140, a transparent substrate 150.

The piezoelectric polymer layer 110 is an element that implements a haptic feedback function on the haptic feedback screen 100 and is formed of a transparent piezoelectric polymer material.

Since voltage is generated when pressure is applied to a piezoelectric material and since transformation is generated when voltage is applied to the piezoelectric material, the piezoelectric material is used in various sensors and actuators. The piezoelectric material includes piezoelectric ceramics such as lead zirconate titanates (PZT) and piezoelectric polymers such as poly vinylidene fluoride (PVDF). Particularly, the P(VDF-TrFE) made up of a combination of two monomolecular vinylidene fluoride (VDF) and trifluoroethylene (TrFE) among the PVDF-based polymers has piezoelectric characteristics higher than those of other piezoelectric polymers.

The piezoelectric polymer layer 110 according to the present exemplary embodiment is formed of a PVDF-based ferroelectric polymer (ex, PVDF, P(VDF-TrFE)) material or a relaxor ferroelectric polymer (ex, P(VDF-TrFE-CFE), P(VDF-TrFE-CTFE), or electron-irradiated P(VDF-TrFE)) material.

The relaxor ferroelectric polymer P(VDF-TrFE-CFE) or P(VDF-TrFE-CTFE) causes a strain of up to about 5 to 7% in an electric field of about 20 to 150 V/μm. The third monomolecular CFE or CTFE introduces an intended defect in the arrangement of the ferroelectric polymer P(VDF-TrFE). Consistent polarized area is divided into nano-polarized area by such an intended defects. That is, all-trans chains(polarized areas) are interrupted by trans and gauche bonds.

When the size of the area decreases in nanometer scale, and energy barrier required for a phase shift of the area or a conversion of a polarization direction is lowered to have advantage. Accordingly, it is possible to easily align the polarization only by a low-level bias voltage. For example, when the relaxor polymer is used, it is possible to easily align the polarization only by the low-level bias voltage and a separate polarization process is not required unlike the P(VDF-TrFE).

The upper electrode 120 and the lower electrode 130 are electrodes for driving the piezoelectric polymer layer 110. The upper electrode 120 and the lower electrode 130 are respectively disposed on an upper surface and a lower surface of the piezoelectric polymer layer 110, and formed of a transparent material. An AC voltage applied to the two electrodes 120 and 130 is applied to the piezoelectric polymer layer 110, and the piezoelectric polymer layer 110 converts the applied electrical energy into a mechanical vibration energy.

The upper electrode 120 and the lower electrode 130 may be formed of a transparent conductive oxide (TCO) such as indium-tin oxide (ITO) and indium zinc oxide (IZO), and may be formed as a conductive polymer electrode such as poly (3,4-ethylenedioxythiophene): poly(styrenesulfonate).

The transparent cover 140 is disposed on the upper electrode 120 to cover the haptic feedback screen 100. The transparent cover 140 is a portion which a fingertip or an object directly contacts. The transparent cover 140 may be made of a transparent polymer film such as glass, polyether sulfone (PES), polyether sulfone (PET), polyetheretherketone (PEEK), or polycarbonate.

In addition, the transparent substrate 150 is a base substrate disposed under the lower electrode 130 and serves to be a mother material of the screen. The transparent substrate 150 may be made of the same material as the above-described transparent cover 140 or other transparent materials.

In the configuration of the first exemplary embodiment, when a touch occurs on the transparent cover, the piezoelectric polymer layer 110 generates a vibration in the touch region by a power applied between the upper electrode 120 and the lower electrode 130. That is, the piezoelectric polymer layer 110 implements a haptic feedback function by converting the applied electrical energy into the mechanical energy.

The haptic feedback function generally operates together with a touch sensor. For this purpose, a capacitive type or resistive type touch sensor (not shown) may be combined with the haptic feedback screen 100. For example, the touch sensor may be provided under the lower electrode 130 or over the upper electrode 120. However, the present invention is not limited thereto.

Such a touch sensor senses whether a touch is generated on the transparent cover 140, and when it is determined that the touch is generated, the touch sensor applies an electrical energy between the upper electrode 120 and the lower electrode 130. The applied electrical energy is converted into a mechanical vibration energy in the piezoelectric polymer layer 110.

In the present exemplary embodiment, when a fingertip or an object contacts the transparent cover 140, the touch sensor applies an AC voltage between the two electrodes 120 and 130, and thus the piezoelectric polymer layer 110 is driven to generate an acoustic wave. The acoustic wave is directly transmitted to the user's fingertip by vibration. In this case, it is effective to use an audible frequency of about 100 Hz to 20 kHz as a frequency of the AC voltage applied between the two electrodes 120 and 130.

All of the piezoelectric polymer layer 110, the upper electrode 120, the lower electrode 130, the transparent cover 140, and transparent substrate 150 shown in FIG. 1 are respectively made of a transparent material. This is to ensure that light transmitted from the display element disposed under the transparent substrate 150 passes through the upside thereof.

As described above, the transparent substrate 150 and the transparent cover 140 are formed of glass or a transparent polymer, and the upper electrode 120 and the lower electrode 130 are formed as a transparent electrode such as ITO. Since the PVDF-based piezoelectric polymer, which is a material of the piezoelectric polymer layer 110, has a very high transparency with a light transmittance of about 93% with respect to a standard thickness of about 1 mm thereof, it may be used as a very preferable piezoelectric polymer to the present exemplary embodiment.

Further, all of the piezoelectric polymer layer 110, the upper electrode 120, the lower electrode 130, the transparent cover 140, and the transparent substrate 150 may be formed of a flexible material. Accordingly, an entirely flexible transparent haptic feedback screen 100 may be implemented.

FIG. 2 illustrates a cross sectional view of a haptic feedback screen using a piezoelectric polymer according to a second exemplary embodiment of the present invention. Referring to FIG. 2, a haptic feedback screen 200 according to a second exemplary embodiment of the present invention includes a piezoelectric polymer layer 210, an upper electrode 220, a lower electrode 230, a transparent cover 240, a transparent substrate 250, and a spacer 260. Herein, materials of the piezoelectric polymer layer 210, the upper electrode 220, the lower electrode 230, the transparent cover 240, the transparent substrate 250 are referred to those of the first exemplary embodiment.

The piezoelectric polymer layer 210 is formed of a transparent piezoelectric polymer material, and as described above, it is a portion that implements a haptic feedback function.

The upper electrode 220 is disposed over the piezoelectric polymer layer 210 with a gap therebetween and formed of a flexible and transparent material. The transparent cover 240 is disposed on the upper electrode 220 and formed of a flexible material.

The spacer 260 is disposed at edge between the piezoelectric polymer layer 210 and the upper electrode 220 to form the gap between the upper electrode 220 and the piezoelectric polymer layer 210. The spacer 260 may be wholly or intermittently disposed along the edge. Since the spacer 260 may be disposed on an outer circumference frame of the screen 200, they are not necessarily formed of a transparent material.

The lower electrode 230 is disposed on a lower surface of the piezoelectric polymer layer 210 and formed of a transparent material. The transparent substrate 250 is disposed under the lower electrode 230.

According to the second exemplary embodiment, the upper electrode 220 is formed to be lifted from the piezoelectric polymer layer 210 by the spacer 260. Accordingly, the upper electrode 220 and the transparent cover 240 are formed of a flexible material, such that a bent deformation may occur when being touched.

FIG. 3 illustrates an example of driving the exemplary embodiment of FIG. 2. In the second exemplary embodiment, when a touch occurs on the transparent cover 240, a bent deformation occurs in the transparent cover 240 and the upper electrode 220, a deformed portion of the upper electrode 220 contacts a partial surface of the piezoelectric polymer layer 210, and at the same time, an electric field partially increases in the partial surface of the piezoelectric polymer layer 210, such that an acoustic wave is generated.

That is, in the second exemplary embodiment, the electric field partially increases at the point which the fingertip contacts, and thus the haptic feedback is transmitted to the fingertip. Further, if the acoustic wave occurs in such a contact state, the fretting phenomenon (minute amplitude movement between two pushed and contacted surfaces) is generated, thereby further improving the haptic feedback effect. Unlike the first exemplary embodiment, the second exemplary embodiment may implement the partial haptic feedback function in the portion in which the touch is generated, without the separate touch sensor.

The second exemplary embodiment may also include a capacitive type or resistive type touch sensor (not shown). In this case, the touch sensor senses whether a touch is generated on the transparent cover 240, and when that the touch is generated is determined, the touch sensor applies an electrical energy between the upper electrode 220 and the lower electrode 230.

When the touch is generated, the transparent cover 240 and the upper electrode 220 are bent and deformed and thus the upper electrode 230 contacts the piezoelectric polymer layer 210, such that the electrical energy is transmitted to the piezoelectric polymer layer 210. That is, when the touch is generated on the transparent cover 240, the piezoelectric polymer layer 210 converts the electrical energy applied between the upper electrode 220 and the lower electrode 230 into the mechanical energy, thereby implementing the haptic feedback function. In other words, when the touch is generated on the transparent cover 240, the piezoelectric polymer layer 210 generates the vibration in a touch region by the power applied between the upper electrode 220 and the lower electrode 230.

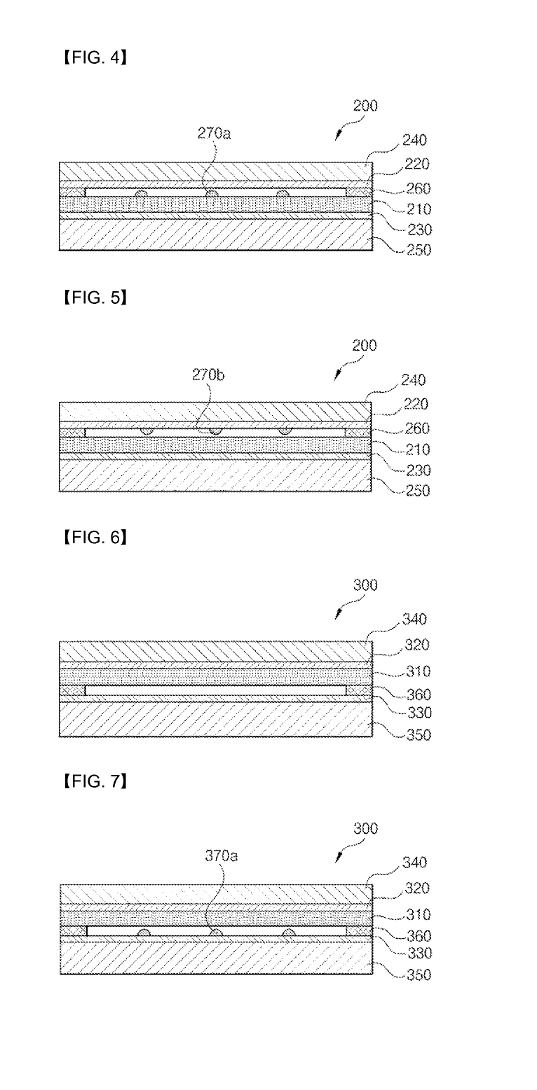

FIGS. 4 and 5 illustrate exemplary diagrams in which dot spacers are included in the exemplary embodiment of FIG. 2. When the haptic feedback screen 200 is a large size, it may be difficult to constantly maintain a distance between the upper electrode 220 and the piezoelectric polymer layer 210 by only the spacer 260. Therefore, dot spacers 270a and 270b may be further provided to avoid malfunction of the screen.

The dot spacers 270a and 270b are formed of a transparent material, have a height lower than the gap, and are arranged in a constant interval on an upper surface (refer to FIG. 4) of the piezoelectric polymer layer 210 or a lower surface (refer to FIG. 5) of the upper electrode 220, corresponding to the inside of the edge. That is, the dot spacers 270a and 270b are intermittently disposed on the inside in which the spacer 260 are not disposed to assist the spacer 260. The dot spacers 270a and 270b are formed of a transparent material of several hundred micrometers or less not to reduce visibility or clarity of the display device.

An exemplary embodiment in which a touch sensor is applied on the haptic feedback screen of FIG. 4 will be described. The resistive type touch sensor has a structure in which a transparent electrode is coated inside a special film, and the resistive type touch sensor may be formed under transparent cover 240 or over the piezoelectric polymer layer 210. If necessary, the electrode used in the touch sensor and the upper electrode 220 may be properly patterned and organically configured.

The capacitive type touch sensor is one that detects a touch position by recognizing a portion in which an amount of current is changed using the capacitance in the body. If the capacitive type touch sensor is disposed under the lower electrode 230, when a touch occurs, a contact of a fingertip may not be sensed. Accordingly, the touch sensor should be disposed on the upper electrode 220. If the touch sensor is required to be disposed under the lower electrode 230, the upper electrode 220 and the lower electrode 230 should be pattered in a special predetermined method.

In the above-described second exemplary embodiment, the transparent cover 240 and the upper electrode 220 are basically formed to be flexible and other components such as the piezoelectric polymer layer 210, the lower electrode 230, the transparent substrate 250, the spacer 260, and the dot spacers 270a and 270b may also be formed of a flexible material. In this case, an entirely flexible transparent haptic feedback screen 200 may be implemented.

FIG. 6 illustrates a cross sectional view of a haptic feedback screen using a piezoelectric polymer according to a third exemplary embodiment of the present invention. Referring to FIG. 6, a haptic feedback screen 300 according to a third exemplary embodiment of the present invention includes a piezoelectric polymer layer 310, an upper electrode 320, a lower electrode 330, a transparent cover 340, a transparent substrate 350, and spacer 360. Materials of the piezoelectric polymer layer 310, the upper electrode 320, the lower electrode 330, the transparent cover 340, and the transparent substrate 350 correspond to those of the first exemplary embodiment.

The piezoelectric polymer layer 310 is formed of a flexible and transparent piezoelectric polymer material, and as described above, it is a portion that implements a haptic feedback function.

The upper electrode 320 is disposed on an upper surface of the piezoelectric polymer layer 310 and formed of a flexible and transparent material. The transparent cover 340 is disposed on the upper electrode 320 and formed of a flexible material.

The lower electrode 330 is disposed under the piezoelectric polymer layer 310 with a gap therebetween and formed a transparent material. The transparent substrate 350 is disposed under the lower electrode 330.

The spacer 360 are disposed at edge between the piezoelectric polymer layer 310 and the lower electrode 330 to form the gap between the piezoelectric polymer layer 310 and the lower electrode 330. The spacer 360 may be wholly or intermittently disposed along the edge like the second exemplary embodiment. Since the spacer 360 may be disposed on an outer circumference frame of the screen 300, they are not necessarily formed of a transparent material.

According to the structure of the third exemplary embodiment, the piezoelectric polymer layer 310 is formed to be lifted from the lower electrode 330 by the spacer 360. The piezoelectric polymer layer 310, the upper electrode 320, and the transparent cover 340 are formed of a flexible material, such that a bent deformation may occur when being touched.

In the third exemplary embodiment, when a touch occurs on the transparent cover 340, a bent deformation occurs in the transparent cover 340, the upper electrode 320, and piezoelectric polymer layer 310, a deformed portion of the piezoelectric polymer layer 310 contacts a partial surface of the lower electrode 330, and at the same time, an electric field partially increases in the deformed portion of the piezoelectric polymer layer 310, such that an acoustic wave is generated.

That is, in the third exemplary embodiment like the second exemplary embodiment, the electric field partially increases at the point which the fingertip contacts, and thus the haptic feedback is transmitted to the fingertip. As such, if the acoustic wave occurs in such a contact state, the fretting phenomenon is generated, thereby further improving the haptic feedback effect. Similar to second exemplary embodiment, the third exemplary embodiment may implement the partial haptic feedback function in the portion in which the touch is generated, without the separate touch sensor.

The third exemplary embodiment may also include a capacitive type or resistive type touch sensor (not shown). In this case, the touch sensor senses whether a touch is generated on the transparent cover 340, and when it is determined that the touch is generated, the touch sensor applies an electrical energy between the upper electrode 320 and the lower electrode 330.

When the touch is generated, the transparent cover 340, the upper electrode 320, and the piezoelectric polymer layer 310 are bent and deformed and then contact the lower electrode 330, such that the electrical energy is transmitted to the piezoelectric polymer layer 310. That is, when the touch is generated on the transparent cover 340, the piezoelectric polymer layer 310 converts the electrical energy applied between the upper electrode 320 and the lower electrode 330 into the mechanical energy, thereby implementing the haptic feedback function. In other words, when the touch is generated on the transparent cover 340, the piezoelectric polymer layer 310 generates the vibration in a touch region by the power applied between the upper electrode 320 and the lower electrode 330.

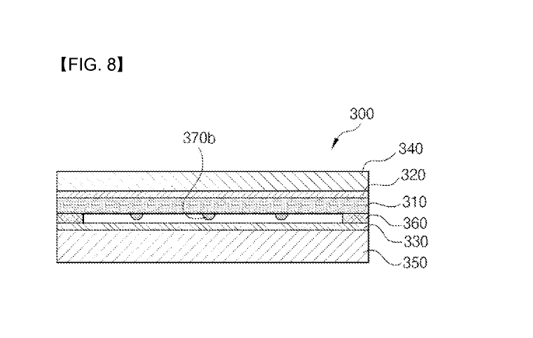

FIGS. 7 and 8 illustrate an exemplary diagram in which dot spacers are included in the exemplary embodiment of FIG. 6. When the haptic feedback screen 300 is a large size, it may be difficult to constantly maintain a distance between the piezoelectric polymer layer 310 and the lower electrode 330 by only the spacer 360. Therefore, dot spacers 370a and 370b may be further provided to avoid malfunction of the screen.

The dot spacers 370a and 370b are formed of a transparent material, have a height lower than the gap, and are arranged in a constant interval on a lower surface (refer to FIG. 8) of the piezoelectric polymer layer 310 or an upper surface (refer to FIG. 7) of the the lower electrode 330, corresponding to the inside of the edge. That is, the dot spacers 370a and 370b are intermittently disposed on the inside in which the spacer 360 are not disposed to assist the spacer 360. The dot spacers 370a and 370b are formed of a transparent material of several hundred micrometers or less not to reduce visibility or clarity of the display device.

In the above-described third exemplary embodiment, the transparent cover 340, the upper electrode 320, and the piezoelectric polymer layer 310 are basically formed to be flexible and other components such as the lower electrode 330, the transparent substrate 350, the spacer 360, and the dot spacers 370a and 370b may also be formed of a flexible material. In this case, an entirely flexible transparent haptic feedback screen 300 may be implemented.

In the first to third exemplary embodiments, the transparent substrates 150, 250, and 350 may be formed of a material of higher strength than those of the transparent covers 140, 240, and 340. As such, when the materials are different in strength, it is possible to further maximize the vibration effect.

As described above, according to the haptic feedback screen using the piezoelectric polymer of the present invention, it is possible to implement an overall or partial haptic feedback function by applying the transparent piezoelectric polymer material to the touch screen. In addition, according to the exemplary embodiments of the present invention, it is possible to provide a transparent and flexible driver capable of implementing a haptic feedback on a touch screen.

A vibration type of touch screen using a haptic feedback in the related art uses a method that a terminal itself vibrates when a touch is sensed, but it does not directly provide a vibration at the touched portion. Accordingly, when a finger touches the touch screen, the hand gripping the touch screen device actually feels the vibration. In the related art, a partial vibration is not implemented in the touch screen device itself.

On the contrary, the haptic feedback screen according to the exemplary embodiment of the present invention may provide, as described above, a partial vibration effect on the touch screen. The haptic feedback screens according to exemplary embodiments of the present invention are preferably manufactured in an array form.

As such, when the haptic feedback screen is manufactured in the array form, a partial vibration function by a touch may be further effectively implemented on a device including a mobile terminal (for example, a touch phone, a smart phone, and a smart pad) or a touch screen. According to such a partial vibration occurrence, a finger that actually touches the touch screen may directly sense the vibration and power required for vibration may be reduced compared with the gross vibration method in the related art.

The haptic feedback screen according to the exemplary embodiment of the present invention may be applied to various devices such as a portable display device, a flexible display device, and an optical instrument. For example, a tablet PC, which is a portable electronic device in the limelight recently, includes a display device of a size of about 7 to 11 inches and uses a touch-based user interface (UI).

As the size of the display device is large, the haptic feedback technology of the gross vibration method used in the mobile phone of the related art become inefficient and thus is difficult to use. On the other hand, since the exemplary embodiment of the present invention may be applicable to a large size of portable display device such as the tablet PC, it may be provided a partial haptic feedback technology by providing a transparent piezoelectric actuator on the surface of the display device.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A haptic feedback screen using a piezoelectric polymer, comprising:
a piezoelectric polymer layer formed of a transparent piezoelectric polymer material;
an upper electrode and a lower electrode respectively disposed on an upper surface and a lower surface of the piezoelectric polymer layer and formed of a transparent material;
a transparent cover disposed over the upper electrode; and
a transparent substrate disposed under the lower electrode,
wherein the piezoelectric polymer layer generates a vibration in a touch region by a power applied between the upper electrode and the lower electrode when a touch occurs on the transparent cover.

2. A haptic feedback screen using a piezoelectric polymer, comprising:
a piezoelectric polymer layer formed of a transparent piezoelectric polymer material;
an upper electrode disposed over the piezoelectric polymer layer with a gap therebetween and formed of a flexible and transparent material;
a transparent cover disposed over the upper electrode and formed of a flexible material;
spacer disposed at edge between the piezoelectric polymer layer and the upper electrode to form the gap;
a lower electrode disposed on a lower surface of the piezoelectric polymer layer and formed of a transparent material; and
a transparent substrate disposed under the lower electrode.

3. A haptic feedback screen using a piezoelectric polymer, comprising:
a piezoelectric polymer layer formed of a flexible and transparent piezoelectric polymer material;
a lower electrode disposed under the piezoelectric polymer layer with a gap therebetween and formed of a transparent material;
a transparent substrate disposed under the lower electrode;
spacer disposed at edge between the piezoelectric polymer layer and the lower electrode to form the gap;
an upper electrode disposed on an upper surface of the piezoelectric polymer layer and formed of a flexible and transparent material; and
a transparent cover disposed over the upper electrode and formed of a flexible material.

4. The haptic feedback screen using the piezoelectric polymer of claim 2, wherein when a touch occurs on the transparent cover, the transparent cover and the upper electrode are bent and deformed, a deformed portion of the upper electrode contacts a partial surface of the piezoelectric polymer layer, and at the same time, an electric field partially increases in the partial surface of the piezoelectric polymer layer, such that an acoustic wave is generated.

5. The haptic feedback screen using the piezoelectric polymer of claim 3, wherein wherein when a touch occurs on the transparent cover, the piezoelectric polymer layer together with the transparent cover and the upper electrode are bent and deformed, a deformed portion of the piezoelectric polymer layer contacts a partial surface of the lower electrode, and at the same time, an electric field partially increases in the deformed portion of the piezoelectric polymer layer, such that an acoustic wave is generated.

6. The haptic feedback screen using the piezoelectric polymer of claim 2, wherein the piezoelectric polymer layer, the lower electrode, the spacer, and the transparent substrate are formed of a flexible material.

7. The haptic feedback screen using the piezoelectric polymer of claim 2, wherein the piezoelectric polymer layer generates a vibration in the touch region by a power applied between the upper electrode and the lower electrode when a touch occurs on the transparent cover.

8. The haptic feedback screen using the piezoelectric polymer of claim 1, wherein the transparent substrate is formed of a material of higher strength than that of the transparent cover.

9. The haptic feedback screen using the piezoelectric polymer of claim 1, wherein the piezoelectric polymer layer is formed of a ferroelectric polymer material of PVDF or P(VDF-TrFE) or formed a relaxor ferroelectric polymer material of P(VDF-TrFE-CFE), P(VDF-TrFE-CTFE), or electron-irradiated P(VDF-TrFE).

10. The haptic feedback screen using the piezoelectric polymer of claim 2, further comprising a plurality of dot spacers formed of a transparent material, having a height lower than the gap, and arranged to assist the spacers in a constant interval on an upper or lower surface of the piezoelectric polymer layer, a lower surface of the upper electrode, or an upper surface of the lower electrode that corresponds to the inside of the edges.

11. The haptic feedback screen using the piezoelectric polymer of claim 3, wherein the piezoelectric polymer layer, the lower electrode, the spacer, and the transparent substrate are formed of a flexible material.

12. The haptic feedback screen using the piezoelectric polymer of claim 3, wherein the piezoelectric polymer layer generates a vibration in the touch region by a power applied between the upper electrode and the lower electrode when a touch occurs on the transparent cover.

13. The haptic feedback screen using the piezoelectric polymer of claim 2, wherein the transparent substrate is formed of a material of higher strength than that of the transparent cover.

14. The haptic feedback screen using the piezoelectric polymer of claim 3, wherein the transparent substrate is formed of a material of higher strength than that of the transparent cover.

15. The haptic feedback screen using the piezoelectric polymer of claim 2, wherein the piezoelectric polymer layer is formed of a ferroelectric polymer material of PVDF or P(VDF-TrFE) or formed a relaxor ferroelectric polymer material of P(VDF-TrFE-CFE), P(VDF-TrFE-CTFE), or electron-irradiated P(VDF-TrFE).

16. The haptic feedback screen using the piezoelectric polymer of claim 3, wherein the piezoelectric polymer layer is formed of a ferroelectric polymer material of PVDF or P(VDF-TrFE) or formed a relaxor ferroelectric polymer material of P(VDF-TrFE-CFE), P(VDF-TrFE-CTFE), or electron-irradiated P(VDF-TrFE).

17. The haptic feedback screen using the piezoelectric polymer of claim 3, further comprising a plurality of dot spacers formed of a transparent material, having a height lower than the gap, and arranged to assist the spacers in a constant interval on an upper or lower surface of the piezoelectric polymer layer, a lower surface of the upper electrode, or an upper surface of the lower electrode that corresponds to the inside of the edges.
